(19) United States
(12) Patent Application Publication
(10) Pub. No.: US 2022/0004400 A1
(43) Pub. Date: Jan. 6, 2022

(54) FPGA-BASED DATA PROCESSING METHOD, APPARATUS, DEVICE AND MEDIUM

(71) Applicant: ZHENGZHOU YUNHAI INFORMATION TECHNOLOGY CO., LTD., Zhengzhou, Henan (CN)

(72) Inventors: Jiaheng FAN, Zhengzhou, Henan (CN); Hongwei KAN, Zhengzhou, Henan (CN)

(73) Assignee: ZHENGZHOU YUNHAI INFORMATION TECHNOLOGY CO., LTD., Zhengzhou, Henan (CN)

(21) Appl. No.: 17/281,259

(22) PCT Filed: Aug. 30, 2019
(86) PCT No.: PCT/CN2019/103693

§ 371 Date: Mar. 30, 2021

(30) Foreign Application Priority Data
Nov. 1, 2018 (CN) 201811295880.4

(51) Int. Cl. G06F 9/445; G06F 12/02

(52) U.S. Cl. CPC G06F 9/44521; G06F 2212/7202; G06F 12/0246

(57) ABSTRACT

A method, an apparatus, a device and a medium for processing data based on an FPGA are provided. In the method, computing circuit resources of the FPGA are divided into N DPR spaces based on a preset space threshold, where N is a positive integer greater than 1. When a target type of data is acquired, a corresponding number of the DPR spaces are selected and target firmware corresponding to the target type is loaded into the selected DPR spaces. Then the target firmware is executed to process the target type of data.

The present application claims priority to Chinese Patent Application No. 201811295880.4, titled “FPGA-BASED DATA PROCESSING METHOD, APPARATUS, DEVICE AND MEDIUM”, filed with the China National Intellectual Property Administration on Nov. 1, 2018, which is incorporated herein by reference in its entirety.

### FIELD

The present disclosure relates to the field of data processing, and in particular to a method, an apparatus and a device for processing data based on an FPGA, and a medium.

### BACKGROUND

With development of internet technology, more and more types of services are realized with network resources, and more and more servers are built to perform data logical operations such as cloud computing, big data processing, and asset transactions.

Since servers are not apt at data operations, it is not cost-effective to improve computing capability by increasing the quantity of service servers, as it is costly and can only provide very limited improvement to the computing capability. In a conventional solution, an FPGA (Field-Programmable Gate Array) board is connected to a server so as to increase resources for data operations of the server. By performing data operations with the FPGA, the server can benefit from the characteristics of gate circuit of the FPGA, and therefore obtain an improved capability for data operation. When the PFGA board is used by the server, a firmware is loaded into the FPGA according to current requirements for data operation. Operation logic in the firmware is executed by the operation resources of the FPGA to perform data operations. At present, the FPGA is usually used as an integral resource to be loaded with firmware, that is, the whole FPGA, once being used, is used to execute a single type of firmware to operate a corresponding type of data. However, data to be processed normally has various types and a varying amount. Therefore, the current FPGA being used to process only a single type of data at a time results in poor flexibility and therefor cause waste of resources.

In view of this, it is desired in the art to propose a method for processing data based on an FPGA, which can improve the flexibility of using the FPGA and avoid waste of FPGA resources.

### SUMMARY

An objective of the present disclosure is to provide a method, an apparatus and a device for processing data based on an FPGA, and a medium, to improve the flexibility of using the FPGA and avoid waste of FPGA resources.

In order to solve the above technical problem, a method for processing data based on an FPGA is provided according to the present disclosure. The method includes: dividing computing circuit resources of the FPGA into N DPR spaces based on a preset space threshold, where N is a positive integer greater than 1; when a target type of data is acquired, selecting a corresponding number of DPR spaces and loading target firmware corresponding to the target type into the selected DPR spaces; and executing the target firmware to process the target type of data.

Preferably, after the executing the target firmware to process the target type of data, the method further includes: when a new target type of data is acquired, selecting a preset number of DPR spaces as target DPR spaces and unloading the target firmware in the target DPR spaces; and loading new target firmware corresponding to the new target type of data into the target DPR spaces, and executing the new target firmware to process the new target type of data.

Preferably, when only the target type of data is acquired by the FPGA, the selecting a corresponding number of DPR spaces and loading target firmware corresponding to the target type into the selected DPR spaces comprises: selecting the N DPR spaces and loading the target firmware into the N DPR spaces.

Preferably, when the new target type of data has a higher priority than the target type of data, the preset number is more than N/2.

Preferably, the selecting a corresponding number of DPR spaces and loading target firmware corresponding to the target type into the selected DPR spaces includes: selecting the corresponding number of DPR spaces based on a total amount of the target type of data and loading the target firmware corresponding to the target type into the selected DPR spaces, where the corresponding number of the DPR spaces is positively correlated with the total amount of the target type of data.

Preferably, the target firmware is pre-stored in a FLASH memory of the FPGA.

An apparatus for processing data based on an FPGA is further provided according to the present disclosure. The apparatus includes: a space dividing module configured to divide computing circuit resources of the FPGA into N DPR spaces based on a preset space threshold, where N is a positive integer greater than 1; a firmware loading module configured to select, when a target type of data is acquired, a corresponding number of DPR spaces and load target firmware corresponding to the target type into the selected DPR spaces; and a data processing module configured to execute the target firmware to process the target type of data.

Preferably, the apparatus further includes: a space releasing module configured to select, when a new target type of data is acquired, a preset number of DPR spaces as target DPR spaces and unload the target firmware in the target DPR spaces; and a new data processing module configured to load new target firmware corresponding to the new target type of data into the target DPR spaces, and execute the new target firmware to process the new target type of data.

A device for processing data based on an FPGA is further provided according to the present disclosure. The device includes: a memory configured to store a computer program; and a processor configured to execute the computer program to implement steps of the above method for processing data based on an FPGA.

A computer readable storage medium is further provided according to the present disclosure. The computer readable storage medium stores a computer program that, when executed by a processor, implements steps of the above method for processing data based on an FPGA.

In the method for processing data based on an FPGA provided according to the present disclosure, first computing circuit resources of the FPGA are divided into more than one DPR spaces based on a preset space threshold. Then when a target type of data is acquired, a corresponding number of DPR spaces in the FPGA are selected and loaded with target firmware for processing the target device, and the target type of data is thereby processed through the target firmware. By quantifying the hardware resources in an FPGA to generate corresponding DPR spaces, and then selecting a corresponding number of DPR spaces based on the acquired target type of data and loading corresponding target firmware into the DPR spaces to process the target type of data, the method achieves selectively occupying a part of the FPGA resources for data processing. The remaining FPGA resources may be used for processing other target types of data. Therefore, the flexibility of using FPGA is improved, and waste of FPGA resources is reduced. In addition, an apparatus and a device for processing data based on an FPGA, and a medium are provided according to the present disclosure, which have the same beneficial effects as described above.

### BRIEF DESCRIPTION OF THE DRAWINGS

FIG. 1 is a flow chart of a method for processing data based on an FPGA according to an embodiment of the present disclosure;

FIG. 2 is a flow chart of a method for processing data based on an FPGA according to another embodiment of the present disclosure; and

FIG. 3 is a structural diagram of an apparatus for processing data based on an FPGA according to an embodiment of the present disclosure.

### DETAILED DESCRIPTION OF THE EMBODIMENTS

Technical solutions according to embodiments of the present disclosure are clearly and completely described hereinafter in conjunction with the drawings in the embodiments of the present disclosure. It is apparent that the embodiments described herein are only a few rather than all of the embodiments according to the present disclosure. Any other embodiments obtained by those skilled in the art based on the embodiments in the present disclosure without any creative effort shall fall within the protection scope of the present disclosure.

An aspect of the present disclosure is to provide a method for processing data based on an FPGA, which contributes to improving the flexibility of using the FPGA and avoiding waste of FPGA resources. Another aspect of the present disclosure is to provide an apparatus and a device for processing data based on an FPGA, and a medium.

In order for a better understanding of the solutions according to the present disclosure by those skilled in the art, the solutions are illustrated hereinafter in further detail and in conjunction with the drawings and embodiments.

### First Embodiment

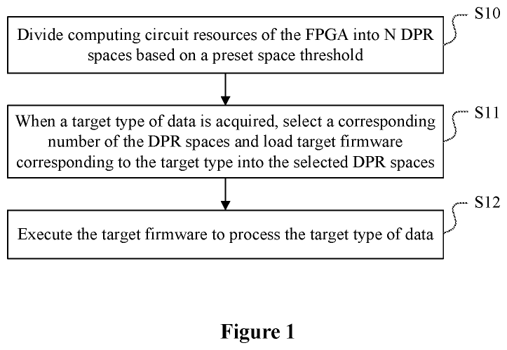

FIG. 1 is a flow chart of a method for processing data based on an FPGA according to an embodiment of the present disclosure. Referring to FIG. 1, the method for processing data based on an FPGA includes the following steps S10 to S12.

In step S10, computing circuit resources of the FPGA are divided into N DPR spaces based on a preset space threshold, where N is a positive integer greater than 1.

It is to be noted that, the DPR (Dynamic Partial Reconfiguration) referred to in this step is a modular design based on FPGA. The purpose of DPR is to divide the resources of the FPGA into several computing modules, i.e., the DPR spaces mentioned above. Each of the DPR spaces is essentially a logic circuit unit and is able to independently perform logic operation processing on data. The preset space threshold mentioned above is set for a space capacity of the DPR spaces. In this step, the FPGA, as an integral computing circuit resource, is divided into DPR spaces. After the division, the FPGA can be regarded as N DPR spaces each capable of performing data operations. Furthermore, N is an integer greater than 1 so that the FPGA is divided into multiple quantified data processing units. On this basis, a specific value of N may be determined according to specific requirements in an actual application, which is not limited herein.

In step S11, when a target type of data is acquired, a corresponding number of DPR spaces are selected and loaded with target firmware corresponding to the target type.

In the step, when a target type of data to be processed is acquired, a number of DPR spaces are selected based on the target type of data. Target firmware corresponding to the target type is then loaded into each of the selected DPR spaces, so that the target type of data can be processed through the corresponding target firmware. The corresponding number mentioned above means the number of DPR spaces that are suitable for processing the target type of data. The corresponding number may be determined according to the number of types of the data to be processed by the FPGA, the amount of the target type of data, or other factors, which is not specifically limited herein.

In step S12, the target firmware is executed to process the target type of data.

In this step, the loaded target firmware is executed in the DPR spaces to process the target type of data through the target firmware based on the computing resources of the DPR spaces. The specific processing logic follows the content of the target firmware being executed. Different target firmware is employed for processing different types of data, and the different target firmware has different contents. The method mainly focuses on selectively loading target firmware for processing a target type of data into a certain number of DPR spaces. Therefore, the definition of the target type and the data processing logic of the target firmware are not detailed described herein.

In the method for processing data based on an FPGA provided according to the present disclosure, first computing circuit resources of the FPGA are divided into more than one DPR spaces based on a preset space threshold. Then when a target type of data is acquired, a corresponding number of DPR spaces in the FPGA are selected and loaded with target firmware for processing the target device, and the target type of data is thereby processed through the target firmware. By quantifying the hardware resources in an FPGA to generate corresponding DPR spaces, and then selecting a corresponding number of DPR spaces based on the acquired target type of data and loading corresponding target firmware into the DPR spaces to process the target type of data, the method achieves selectively occupying a part of the FPGA resources for data processing. The remaining FPGA resources may be used for processing other target types of data. Therefore, the flexibility of using FPGA is improved, and waste of FPGA resources is reduced.

### Second Embodiment

Based on the above embodiment, a number of preferred embodiments are further provided in the present disclosure as follows.

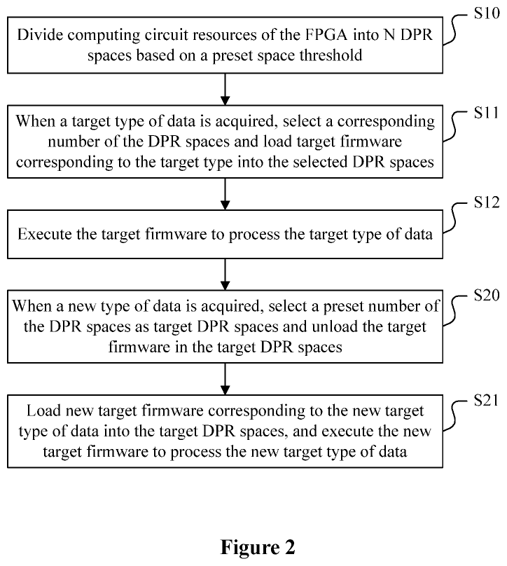

FIG. 2 is a flow chart of a method for processing data based on an FPGA according to another embodiment of the present disclosure. Steps S10 to S12 in FIG. 2 are the same as those in FIG. 1, which are thus not described here.

As shown in FIG. 2, according to a preferred embodiment, after the target firmware being executed to process the target type of data, the method further includes steps S20 and S21.

In step S20, when a new target type of data is acquired, a preset number of DPR spaces are selected as target DPR spaces, and target firmware in the target DPR spaces is unloaded.

It should be noted that, this step occurs in the process of processing the target type of data. When a new target type of data is acquired, in order to ensure enough logic circuit resources in the FPGA, a preset number of DPR spaces are selected as target DPR spaces and target firmware in the target DPR spaces is unloaded, so that the target DPR spaces can be loaded with new target firmware and used to process the new target type of data. In addition, the preset number in this step may be set based on the total amount of the new target type of data, or the priority relation between the new target type and the target type, or other factors, which is not limited herein.

In step S21, new target firmware corresponding to the new target type of data is loaded into the target DPR spaces and is executed to process the new target type of data.

In this step, the target DPR spaces whose target firmware is unloaded in the previous step are loaded with the new target firmware for processing the new target type of data, so that the new target firmware may be executed to process the target type of data using the target DPR spaces as new data processing resources. According to the embodiment, when new target type of data is acquired, the target firmware in the target DPR spaces is unloaded to ensure relative ample DPR space resources, thereby ensuring the overall efficiency when processing the new target type of data.

Based on the above embodiments, as a preferred embodiment, when the FPGA acquires only a target type of data, the selecting a corresponding number of DPR spaces and loading target firmware corresponding to the target type into the selected DPR spaces specifically includes selecting N DPR spaces and loading target firmware into the N DPR spaces.

It should be noted that, for a situation where the FPGA acquires and processes only the target type of data, that is, there is only one type of data to be processed in the FPGA, in order to maximize the efficiency of processing the target type of data, the N DPR spaces that are previously obtained by dividing the resources in the FPGA are all loaded with the target firmware, so that the computing resources of the FPGA are all used for processing the target type of data, thereby maximizing the utilization of the FPGA computing resources and improving the data processing efficiency of the FPGA.

Based on the above embodiments, as a preferred embodiment, when the new target type of data has a higher priority than the target type of data, the preset number is more than N/2.

It should be noted that, according to the embodiment, the number of the target DPR spaces to be released is determined based on the priority relation between the new target type and the target type acquired by the FPGA. If the new target type of data has a priority higher than the target type of data, it indicates that the new target type of data is to be processed preferentially. Therefore, if N DPR spaces are already occupied to process the target type of data, more than half of the DPR spaces are released for processing the new target type data, in order to ensure that the new target type data with high priority is processed more efficiently, thereby improving the overall efficiency of data processing.

Besides, as a preferred embodiments, the selecting a corresponding number of DPR spaces and loading target firmware corresponding to the target type in the selected DPR spaces specifically includes selecting the corresponding number of DPR spaces based on a total amount of the target type of data and loading the target firmware corresponding to the target type into the selected DPR spaces, where the corresponding number of the DPR spaces is positively correlated with the total amount of the target type of data.

According to the embodiment, considering that the total amount of the target type of data is a key factor in determining the time required for processing the target type of data, the corresponding number of DPR spaces are selected based on the total amount of the target type of data, and the selected DPR spaces are loaded with target firmware corresponding to the target type. Further, the corresponding number of the selected DPR spaces is positively correlated with the total amount of the target type of data, thereby ensuring the overall efficiency of processing the target type of data when the corresponding number of DPR spaces is selected based on the total amount of target type of data.

Furthermore, based on the above embodiments, as a preferred embodiment, the target firmware is pre-stored in a FLASH memory of the FPGA.

It should be noted that, compared with the conventional EEPROM memory, the FLASH memory has higher efficiency in data erasing and writing. Furthermore, the FLASH memory has the advantages of both ROM and RAM, not only having a performance of an electrically erasable programmable read-only memory (EEPROM), but also being capable of reading data quickly. Therefore, the overall execution efficiency is relatively high when pre-storing firmware in the FLASH memory of the FPGA and reading and using the firmware in the FLASH memory.

An embodiment of a specific application scenario is provided below.

Hardware resources of an FPGA are firstly quantified to generate a number of DPR spaces, and the firmware for processing different types of data may be used for different service types (such as image service, data analysis service and encrypted data service).

For example, the computing resources of one FPGA are divided into 100 DPR spaces. When an image service is to be executed on the server, 20 DPR spaces on the FPGA may be selected and respectively loaded with target firmware corresponding to the image service, so as to process data of the image service by executing the target firmware. In this case, when a data analysis service is further to be executed on the server, another 50 DPR spaces on the FPGA may be selected and respectively loaded with new target firmware corresponding to the data analysis service, so as to process data of the data analysis service by executing the new target firmware. In this case, 30 DPR spaces in the FPGA are remained for subsequent service.

The above-mentioned mode is a static allocation mode. If the hardware resources of the FPGA are all allocated to services currently performed by the FPGA, when a new service arrives subsequently, the resources should be dynamically scheduled based on priorities of the services. That is, services on the server are assigned with different priorities. For example, when a first service in the server requires FPGA for auxiliary computing, all of the 100 DPR spaces previously obtained by dividing the FPGA may be allocated to the first service. On this basis, when a second service with a relatively high priority is to be executed on the server, 10 DPR spaces will be reserved for basic using by the first service with a relatively low priority and the rest 90 DPR spaces are released to be allocated to the second service. If the server needs to further execute a third service with the same priority as the second service, 45 computing units will be released from the second service to be used by the third service. In this case, all the three services are executed at the same time, respectively occupying 10 DPR spaces, 45 DPR spaces and 45 DPR spaces. If a fourth service with an even higher priority is to be executed on the server using DPR spaces, the second service and the third service may each reserve only 10 DPR spaces. Therefore, the fourth service may be allocated with 70 computing units. The allocation pattern may be: 10, 10, 10, and 70. When a service with a relatively low priority is completed, the DPR spaces used by the service are released, and the released DPR spaces are allocated to a service with a higher priority. In the case of multiple services with a higher priority, the released DPR spaces are evenly allocated to these services.

### Third Embodiment

The embodiments of the method for processing data based on an FPGA are described in detail above. An apparatus for processing data based on an FPGA corresponding to the method is further provided according to the present disclosure. Since the apparatus corresponds to the method disclosed in the embodiments, reference may be made to the description of the method for relevant description of the apparatus, which is not repeated herein.

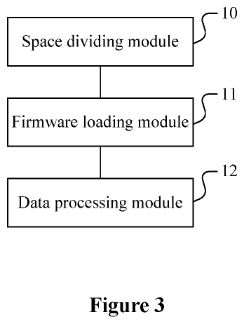

FIG. 3 is a structural diagram of an apparatus for processing data based on an FPGA according to an embodiment of the present disclosure. The apparatus for processing data based on an FPGA according to an embodiment of the present disclosure includes: a space dividing module 10 configured to divide computing circuit resources of the FPGA into N DPR spaces based on a preset space threshold, where N is a positive integer greater than 1; a firmware loading module 11 configured to select, when a target type of data is acquired, a corresponding number of DPR spaces and load target firmware corresponding to the target type into the selected DPR spaces; and a data processing module 12 configured to execute the target firmware to process the target type of data.

The apparatus for processing data based on an FPGA provided according to the present disclosure firstly divides computing circuit resources of the FPGA into more than one DPR spaces based on a preset space threshold, and then when a target type of data is acquired, selects a corresponding number of DPR spaces in the FPGA and loads target firmware for processing the target device into the selected DPR spaces, and processes the target type of data through the target firmware. By quantifying the hardware resources in an FPGA to generate corresponding DPR spaces, and then selecting a corresponding number of DPR spaces based on the acquired target type of data and loading corresponding target firmware into the selected DPR spaces to process the target type of data, the apparatus achieves selectively occupying a part of the FPGA resources for data processing. The remaining FPGA resources may be used for processing other target types of data. Therefore, the flexibility of using FPGA is improved, and waste of FPGA resources is reduced.

Based on the third embodiment, the apparatus for processing data based on an FPGA in the present disclosure may further includes: a space releasing module configured to select, when a new target type of data is acquired, a preset number of DPR spaces as target DPR spaces and unload target firmware in the target DPR spaces; and a new data processing module configured to load new target firmware corresponding to the new target type of data into the target DPR spaces, and execute the new target firmware to process the new target type of data.

### Fourth Embodiment

A device for processing data based on an FPGA is further provided according to the present disclosure. The device includes: a memory configured to store a computer program; and a processor configured to execute the computer program to implement steps of the above method for processing data based on an FPGA.

The device for processing data based on an FPGA provided according to the present disclosure firstly divides computing circuit resources of the FPGA into more than one DPR spaces based on a preset space threshold, and then when a target type of data is acquired, selects a corresponding number of DPR spaces in the FPGA and loads target firmware for processing the target device into the selected DPR spaces; and processes the target type of data through the target firmware. By quantifying the hardware resources in an FPGA to generate corresponding DPR spaces, and then selecting a corresponding number of DPR spaces based on the acquired target type of data and loading corresponding target firmware into the selected DPR spaces to process the target type of data, the device achieves selectively occupying a part of the FPGA resources for data processing. The remaining FPGA resources may be used for processing other target types of data. Therefore, the flexibility of using FPGA is improved, and waste of FPGA resources is reduced.

A computer readable storage medium is further provided according to the present disclosure. The computer readable storage medium stores a computer program that, when being executed by a processor, implements steps of the above method for processing data based on an FPGA.

The computer readable storage medium provided according to the present disclosure firstly divides computing circuit resources of the FPGA into more than one DPR spaces based on a preset space threshold, and when a target type of data is acquired, selects a corresponding number of DPR spaces in the FPGA and loads target firmware for processing the target device into the selected DPR spaces, and processes the target type of data through the target firmware. By quantifying the hardware resources in an FPGA to generate corresponding DPR spaces, and then selecting a corresponding number of DPR spaces based on the acquired target type of data and loading corresponding target firmware into the selected DPR spaces to process the target type of data, the computer readable storage medium achieves selectively occupying a part of the FPGA resources for data processing. The remaining FPGA resources may be used for processing other target types of data. Therefore, the flexibility of using FPGA is improved, and waste of FPGA resources is reduced.

The method, the apparatus, and the device for processing data based on an FPGA, and the medium according to the present disclosure are described in detail above. In the present specification, the embodiments are described in a progressive manner. Each of the embodiments mainly focuses on its differences from other embodiments, and references may be made to each other for the same or similar parts. The apparatus, the device and the medium according to the embodiments are described in a relatively simple manner, as they correspond to the method disclosed in the embodiments. For detailed description of the device, the device and the medium, reference may be made to the related description of the method. It should be noted that, many improvements and modifications may be made to the present disclosure by those skilled in the art without departing from the principle of the present disclosure, and such improvements and modifications shall fall within the protection scope defined by the claims.

It is further noted that in the present disclosure, relational terms such as “first” and “second” are merely used to distinguish one entity or operation from another, rather than to indicate or imply any actual relationship or order of these entities or operations. Furthermore, terms “include”, “comprise” or any other variants thereof are intended to be non-exclusive. Therefore, a process, method, article or device including a series of elements includes not only the elements but also other elements that are not enumerated or other elements inherent to such process, method, article or device. Unless expressively limited otherwise, the statement “comprising (including) a/an . . . ” does not exclude a case where a process, method, article or device that includes the defined element further includes additional identical elements.

1. A method for processing data based on an FPGA, comprising:
dividing computing circuit resources of the FPGA into N DPR spaces based on a preset space threshold, where N is a positive integer greater than 1;
when a target type of data is acquired, selecting a corresponding number of the DPR spaces and loading target firmware corresponding to the target type into the selected DPR spaces; and
executing the target firmware to process the target type of data.

2. The method according to claim 1, wherein after the executing the target firmware to process the target type of data, the method further comprises:
selecting, when a new type of data is acquired, a preset number of the DPR spaces as target DPR spaces and unloading the target firmware in the target DPR spaces; and
loading new target firmware corresponding to the new target type of data into the target DPR spaces, and executing the new target firmware to process the new target type of data.

3. The method according to claim 2, wherein when only the target type of data is acquired by the FPGA, the selecting a corresponding number of DPR spaces and loading target firmware corresponding to the target type into the selected DPR spaces comprises:
selecting the N DPR spaces and loading the target firmware into the N DPR spaces.

4. The method according to claim 3, wherein when the new target type of data has a higher priority than the target type of data, the preset number is more than N/2.

5. The method according to claim 1, wherein the selecting a corresponding number of DPR spaces and loading target firmware corresponding to the target type into the selected DPR spaces comprises:
selecting the corresponding number of the DPR spaces based on a total amount of the target type of data, and loading the target firmware corresponding to the target type into the selected DPR spaces, where the corresponding number of the DPR spaces is positively correlated with the total amount of the target type of data.

6. The method according to claim 1, wherein the target firmware is pre-stored in a FLASH memory of the FPGA.

7. An apparatus for processing data based on an FPGA, comprising:
a space dividing module configured to divide computing circuit resources of the FPGA into N DPR spaces based on a preset space threshold, where N is a positive integer greater than 1;
a firmware loading module configured to select, when a target type of data is acquired, a corresponding number of the DPR spaces and load target firmware corresponding to the target type into the selected DPR spaces; and
a data processing module configured to execute the target firmware to process the target type of data.

8. The apparatus according to claim 7, further comprising:
a space releasing module configured to select, when a new type of data is acquired, a preset number of the DPR spaces as target DPR spaces and unload the target firmware in the target DPR spaces; and
a new data processing module configured to load new target firmware corresponding to the new target type of data into the target DPR spaces and execute the new target firmware to process the new target type of data.

9. A device for processing data based on an FPGA, comprising:
a memory configured to store a computer program; and
a processor configured to execute the computer program to;
divide computing circuit resources of the FPGA into N DPR spaces based on a preset space threshold, where N is a positive integer greater than 1;
when a target type of data is acquired, select a corresponding number of the DPR spaces and load target firmware corresponding to the target type into the selected DPR spaces; and
execute the target firmware to process the target type of data.

10. A computer readable storage medium storing a computer program, the computer program, when being executed by a processor, implementing steps of the method for processing data based on an FPGA according to claim 1.

11. The device according to claim 9, wherein the processor is further configured to:
select, when a new type of data is acquired, a preset number of the DPR spaces as target DPR spaces and unload the target firmware in the target DPR spaces; and
load new target firmware corresponding to the new target type of data into the target DPR spaces, and execute the new target firmware to process the new target type of data.

12. The device according to claim 11, wherein the processor is further configured to:
select, when only the target type of data is acquired by the FPGA, the N DPR spaces and loading the target firmware into the N DPR spaces.

13. The device according to claim 12, wherein when the new target type of data has a higher priority than the target type of data, the preset number is more than N/2.

14. The device according to claim 9, wherein the processor is further configured to:
select the corresponding number of the DPR spaces based on a total amount of the target type of data, and load the target firmware corresponding to the target type into the selected DPR spaces, where the corresponding number of the DPR spaces is positively correlated with the total amount of the target type of data.

15. The device according to claim 9, wherein the target firmware is pre-stored in a FLASH memory of the FPGA.

16. The computer readable storage medium according to claim 10, wherein the computer program further causes the processor to:
select, when a new type of data is acquired, a preset number of the DPR spaces as target DPR spaces and unload the target firmware in the target DPR spaces; and
load new target firmware corresponding to the new target type of data into the target DPR spaces, and execute the new target firmware to process the new target type of data.

17. The computer readable storage medium according to claim 16, wherein the computer program further causes the processor to:
select, when only the target type of data is acquired by the FPGA, the N DPR spaces and loading the target firmware into the N DPR spaces.

18. The computer readable storage medium according to claim 17, wherein when the new target type of data has a higher priority than the target type of data, the preset number is more than N/2.

19. The computer readable storage medium according to claim 10, wherein the computer program further causes the processor to:
select the corresponding number of the DPR spaces based on a total amount of the target type of data, and load the target firmware corresponding to the target type into the selected DPR spaces, where the corresponding number of the DPR spaces is positively correlated with the total amount of the target type of data.

20. The computer readable storage medium according to claim 10, wherein the target firmware is pre-stored in a FLASH memory of the FPGA.
